(19) United States
(12) Patent Application Publication
(10) Pub. No.: US 2021/0333346 A1
(43) Pub. Date: Oct. 28, 2021

(54) MRI data transforming device including an transforming network using an MRI data and additional information and an MRI data transforming method using the same

(71) Applicant: SEOUL NATIONAL UNIVERSITY R&DB FOUNDATION, Seoul (KR)

(72) Inventors: Jongho LEE, Seoul (KR); Woojin JUNG, Seoul (KR)

(21) Appl. No.: 16/792,932

(22) Filed: Apr. 27, 2020

(51) Int. Cl. G01R 33/54; G06T 11/00; G06N 3/04

(52) U.S. Cl. CPC G01R 33/546; G06N 3/04; G01R 33/543; G06T 11/005

(57) ABSTRACT

Provided is an MRI data transform device including a transform network unit configured to output prescribed transform information on the basis of MRI data output from an MRI scanner. The MRI data and information about device characteristics of the MRI scanner are input to the transform network unit.

### BACKGROUND

The present disclosure relates to an MRI data transform technology including a transform network unit for transforming MRI data output from an MRI scanner to prescribed transformed information, and in particular, to a method for training the transform network unit and a method for transforming the MRI data using the trained transform network unit.

FIG. 1 is a diagram showing a method for transforming MRI data 50 output from a magnetic resonance imaging (MRI) scanner 30 according to an embodiment.

For an operation of the MRI scanner 30, user setting parameters 401, 402, and 403 may be present in the MRI scanner 30. Before operating the MRI scanner 30, the user may determine various kinds of user setting parameters 401, 402 and 403 using a user setting parameter determination unit 40 for changing operation settings of the MRI scanner 30. The user setting parameter determination unit 40 may be integrated with or separated from the MRI scanner 30.

The user setting parameters 401, 402, and 403 may include parameters typically referred to as scan parameters and/or other kinds of parameters that may be set by the user. In FIG. 1, three reference numerals 401, 402, and 403 are used for representing the user setting parameters, but the number of the user setting parameters for a particular MRI scanner may be theoretically 0 to several dozen. Hereinafter, in the drawings, the user setting parameters may be represented with a reference sign CPₖ (where k=1, 2, . . . , K).

For example, an operation manner of the MRI scanner 30 may be changed according to concrete values of the user setting parameters 401, 402, and 403. When the operation manner of the MRI scanner 30 is changed, values indicated by the MRI data 50 output from the MRI scanner 30 with respect to an identical scan target may also be changed,

The ‘user setting parameters’ are a technical concept explaining ‘device characteristics’ of the MRI scanner, which are defined and presented in the present disclosure. The present disclosure presents a concept referred to as ‘structure parameters’, as another technical concept explaining the device characteristics of the MRI scanner. The device characteristics of the MRI scanner will be concretely described in the description. Some of the structure parameters may be easily defined and quantified, but others may not.

In the present disclosure, for example, one piece of MRI data 50 may mean a set of values output from the MRI scanner 30 when the MRI scanner 30 completes scanning once for a scan target. A plurality of sets of MRI data 50 may mean a plurality of sets of values output from the MRI scanner 30 when the MRI scanner 30 completes scanning a plurality of times for a scan target.

The user setting parameter determination unit 40 may be operated by a user input interface of the MRI scanner 30 or a separate automated user setting parameter input interface. The user setting parameter determination unit 40 may output the user setting parameters 401, 402, and 403 to be set for the MRI scanner 30.

The MRI data 50 outputs from the MRI scanner 30 may be input to the transform network unit 20. The transform network unit 20 may be set to output transformed information 60 having a predetermined physical meaning on the basis of the input MRI data 50.

The MRI data 50 may be, for example, well-known image data or K-space data. The image data and the K-space data may be mutually transformed.

The transform network unit 20 may be a network that may be trained according to a well-known supervised training manner. For example, the transform network unit 20 may be a convolution neural network (CNN). The transform network unit 20 may include an input layer 210 to which the MRI data 50 or information generated by transforming the MRI data 50 is input, an output layer 230 outputting the transformed information 60, and one or more hidden layers 220 present between the input layer 210 and the output layer 230.

For example, when one set of the MRI data 50 is input to the transform network unit 20, a label 510 corresponding to the input MRI data 50 may be provided in advance. The label 510 may be a kind of answer that the transform network unit 20 intends to output in correspondence to the MRI data 50. For example, the label 510 may be a result value that a skilled MRI data transform expert (e.g., a person) directly observes and determines. The directly observed and determined result value, namely, the label 510 may be the same kind and have the same meaning as the transformed information 60.

An error calculation unit 520 may output an error (Err) 521 calculated on the basis of the difference between a value acquired from the transformed information 60 output from the transform network unit 20 to which the MRI data 50 is input, and a value of the label 510 corresponding to the input MRI data 50.

When the error (Err) 521 has a non-zero value, the transform network unit 20 may be determined not to reach a prescribed intended function or performance, and accordingly, an operation state or an internal configuration of the transform network unit 20 may be changed.

An update control unit 530 may generate, on the basis of a value of the error (Err) 521, network update information 531 for changing the operation state or the internal configuration of the transform network unit 20. The changing of the operation state or the internal configuration may mean to change weights allocated to links to which signal transfer characteristics between nodes are granted, the nodes forming the transform network unit 20.

The network update information 531 generated by the update control unit 530 may be provided to the transform network unit 20. Internal parameters of the transform network unit 20 may be updated on the basis of the network update information 531. For example, each of the input layer 210, the hidden layer 220, and the output layer 230 of the transform network unit 20 may have a plurality of nodes, and arbitrary nodes in different layers may be mutually connected by the weighted links. The internal parameters of the transform network 20 may be the weights.

In FIG. 1, it may be sufficiently understood in a machine-learning field using supervised training that the MRI scanner 30 may train the transform network unit 20 using a plurality of pieces of different MRI data 50, which are output by the MRI scanner 30 that scans different scan targets, and using a plurality of labels 510 respectively corresponding to the plurality of pieces of MRI data 50.

The foregoing label 510, error calculation unit 520, error (Err) 521, update control unit 530, and network update information 531 are examples for assisting understanding of the present disclosure, and the present disclosure is not limited to the configurations thereof and the mutual interaction therebetween.

Here, it is assumed that the transform network unit 20 of FIG. 1 has been sufficiently trained with MRI training data 50, and two scenarios using the trained transform network unit 20 will be checked.

FIG. 2 shows a first transform scenario using the trained transform network unit 20 in FIG. 1.

FIG. 3 shows a second transform scenario using the trained transform network unit 20 in FIG. 1.

First, in an embodiment, in order to prepare the MRI training data to be used in a process for training the transform network unit 20, the user setting parameters 401, 402, and 403 to be set for the MRI scanner 30 may be determined as setting values (CP₁, . . . , CPₖ, . . . , CP_{K}) of a first set. Hereinafter, in descriptions about FIGS. 2 and 3, a situation is assumed in which the first set of setting values (CP₁, . . . CPₖ, . . . , CP_{K}) is used in the process for training the transform network unit 20.

In the transform scenario of FIG. 2, in order to prepare the MRI data 50 that is a transform target that the trained transform network unit 20 should transform, the user setting parameters 401, 402, and 403 to be set for the MRI scanner 130 may be determined as setting values (CP₁, . . . , CPₖ, . . . , CP_{K}) of a second set. The transform scenario of FIG. 2 is a case in which the first set of setting values (CP₁, . . . , CPₖ, . . . , CP_{K}) is the same as the second set of setting values (CP₁, . . . , CPₖ, . . . , CP_{K}).

In the transform scenario of FIG. 3, in order to prepare the transform target MRI data 50 that the trained transform network unit 20 should transform, the user setting parameters 401, 402, and 403 to be set for another MRI scanner 130 may be determined as setting values (CP₁₁, . . . , CPₖ₁, . . . , CP_{K1}) of a third set. The transform scenario of FIG. 3 is a case in which the first set of setting values (CP₁, . . . , CPₖ, . . . , CP_{K}) is different from the third set of setting values (CP₁₁, . . . , CPₖ₁, . . . , CP_{K1}).

A situation may be assumed in which a provider who trains the transform network unit 20 to provide the trained transform network 20 provides the trained transform network unit 20 to a consumer. Here, in order to ensure operation reliability of the trained transform network unit 20, the user setting parameters 50, which are set for obtaining the transform target MRI data 50 that is to be transformed by the trained transform network unit 20, are preferably the same as the user setting parameters set for obtaining the MRI training data 50 used in the process for training the transform network unit 20. In other words, the transform scenario of FIG. 2 is more preferable to the transform scenario of FIG. 3.

However, there may occur a case in which the consumer provided with the trained transform network unit 20 does not know detailed values of the user setting parameters set for obtaining the MRI training data 50, a case in which the consumer does not set the same user setting parameters as the user setting parameters by means of another MRI scanner used by the consumer, or a situation in which, due to different types of the scan target, the user setting parameters, which have been set for obtaining the MRI training data 50, are not set. In such a case, transform performance that would be primarily provided by the trained transform network unit 20 may not be reached.

In addition, as will be described later, due to the difference between the structure parameters of various MRI scanners 30 produced by different engineers, transform performance that would be primarily provided by the trained transform network unit 20 may not be reached.

The difference between the structure parameters may be an output primarily intended in a design process of the MRI scanner. For example, a first fixed magnetic field strength of a first MRI scanner may be designed differently from a second fixed magnetic field strength of a second MRI scanner. To acquire information about the difference may be relatively simple. For example, the first fixed magnetic field strength represents the magnetic intensity of a main magnet of the first MRI scanner.

Furthermore, the difference between the structure parameters may be an output generated by a manufacturing process error between different MRI scanners having the same model number. For example, even when both the first MRI scanner and the second MRI scanner are designed to have the same first fixed magnetic field strength, the fixed magnetic field strengths provided by the two MRI scanner may be different because of the difference in manufacturing process. To acquire information about the difference may be relatively difficult.

In addition, the difference between the structure parameters may be an output generated by different degradation characteristics suffered by internal components of the MRI scanners having the same model number. To acquire information about the difference may be relatively difficult.

### SUMMARY

The present disclosure provides a technology for maintaining transform performance of a trained transform network unit at a constant level in various situations in which the unique device characteristics of an MRI scanner to which the trained transform network unit should be applied are not guaranteed to have a predetermined reference condition.

In accordance with an exemplary embodiment, an MRI data transform device may be provided which includes a transform network unit configured to output prescribed transformed information on the basis of MRI data output from an MRI scanner. Here, in order to output the transformed information, the MRI data and information about the device characteristics of the MRI scanner are provided to the transform network unit.

Here, the information about the device characteristics may include data a characteristic value calculated from the MRI data in a predetermined manner.

Here, the information about the device characteristics may include a user setting parameter of the MRI scanner.

Here, the information about the device characteristics may include a structure parameter indicating a specification of hardware or software constituting the MRI scanner.

Here, the information about the device characteristics may be information about the device characteristics of the MRI scanner at a time point at which the MRI data is generated.

Here, the transform network includes a multi-layer neural network, and the information about the device characteristics may be input to a hidden layer of the neural network.

Here, the information about the device characteristics may be input to one set of nodes constituting the hidden layer, and the information input to the one set of nodes may only include information about the device characteristics.

Here, the number of nodes constituting a third layer connected to an outbound link of an arbitrary node among the one set of nodes may be smaller than the number of nodes constituting an input layer of the neural network.

Here, the MRI data may be image data, and the data characteristic value may include one or more between an SNR and a contrast of the image data.

Here, the MRI data is k-space data, and the data characteristic value may include one or more pieces among power extractable from k-space information, a trajectory in the k-space, and other information.

Here, the transform network unit includes a multi-layer neural network, and input and output characteristics of the hidden layer of the neural network may be changed by the information about the device characteristics.

Here, the hidden layer may include a plurality of channels, and input and output characteristics of a first channel among the plurality of channels may be changed on the basis of the information about the device characteristics.

Here, the MRI scanner is further included, and the transform network unit may be set to receive information about the user setting parameter from the MRI scanner in which the user setting parameter is set.

Here, the MRI scanner and a user setting parameter determination unit, which sets the user setting parameter of the MRI scanner, may be further included, and the transform network unit may be set to receive the information about the user setting parameter from the user setting parameter determination unit.

Here, a parameter conversion unit may be further included, and the transform network unit may include a multi-layer neural network, and the parameter conversion unit is set to acquire the user setting parameter of the MRI scanner, to convert the acquired user setting parameter, and to provide the converted user setting parameter to a hidden layer of the neural network.

Here, information about the device characteristics may include a user setting parameter of the MRI scanner, and the MRI data transform device may further include: a dimension conversion unit which converts a dimension of the user setting parameter to output a first dimension conversion value; and a physical characteristic application unit which converts the first dimension conversion value to output a first conversion parameter on the basis of a first conversion function determined according to a physical meaning of the user setting parameter.

In accordance with another exemplary embodiment, a train method may be provided which trains a transform network unit configured to output prescribed transformed information on the basis of MRI data output from an MRI scanner. The training method may include: acquiring, by an MRI data transform device, information about device characteristics of an MRI scanner; acquiring, by the MRI data transform device, MRI data output from the MRI scanner; acquiring, by the MRI data transform device, a label about the MRI data; inputting, by the MRI data transform device, the MRI data and the information about the device characteristics to the transform network unit and acquiring transformed information from the transform network unit; and updating, by the MRI data transform device, the transform network unit on the basis of a difference value between the transformed information and the label.

Here, the information about the device characteristics may include a user setting parameter of the MRI scanner, and a data characteristic value calculated from the MRI data in a predetermined manner.

Here, the information about the device characteristics may include a user setting parameter of the MRI scanner, and a data characteristic value calculated from the MRI data in a predetermined manner.

Here, the neural network may be a convolution neural network (CNN).

In accordance with another exemplary embodiment, an MRI data transform device may be provided which includes a transform network unit configured to output prescribed transformed information on the basis of MRI data output from an MRI scanner. Here, the transform network unit may be input with □ the MRI data output from the MRI scanner, □ user setting parameter information about the MRI scanner, and □ a data characteristic value calculated from the MRI data in a predetermined manner, wherein the user setting parameter information and the data characteristic value may be input to a hidden layer of a neural network constituting the transform network unit.

In accordance with another exemplary embodiment, a training method of an MRI data transform device may be provided, the training method including: determining, by a user setting parameter determination unit of an MRI data transform device, user setting parameters of an MRI scanner; scanning, by the MRI scanner of the MRI data transform device, a given scan target to output MRI data; extracting, a characteristic extraction unit of the MRI data transform device, a data characteristic value of the MRI data; and supervised-training, by the MRI data transform device, the transform network unit of the MRI data transform device using the output MRI data and a previously prepared label corresponding to the output MRI data, wherein input training data for the supervised training includes not only the output MRI data but also one or more among the determined user setting parameters and the extracted data characteristic value.

In accordance with another exemplary embodiment, an MRI data transform method may be provided which includes: determining, by a user setting parameter determination unit of an MRI data transform device, user setting parameters of an MRI scanner; scanning, by the MRI scanner of the MRI data transform device, a given scan target to output the MRI data; extracting, a characteristic extraction unit of the MRI data transform device, a data characteristic value of the MRI data; and inputting, by the MRI data transform device, not only the output MRI data but also one or more of the determined user setting parameters and the extracted data characteristic value to a trained transform network unit and outputting prescribed transformed information from the trained transform network unit.

In accordance with another exemplary embodiment, an MRI data transform device may be provided which includes a transform network unit configured to output prescribed transformed information transformed from MRI data on the basis of first MRI data output from a first MRI scanner that has scanned a scan target. Here, for outputting the transformed information, the first MRI data and information about device characteristics of the first MRI scanner are set to be provided to the transform network unit, and the device characteristics of the first MRI scanner are formed of parameter values causing a difference between the first MRI data and second MRI data output from a second MRI scanner that is different from the first MRI scanner and has scanned the scan target.

Here, the parameter values may include one or more among a user setting parameter for determining an operation state of the first MRI scanner, a structure parameter representing a specification of first hardware or first software constituting the first MRI scanner, and a data characteristic value acquired from the first MRI data.

### BRIEF DESCRIPTION OF THE DRAWINGS

Exemplary embodiments can be understood in more detail from the following description taken in conjunction with the accompanying drawings, in which:

FIG. 1 is a diagram showing a method for transforming MRI data 50 output from an MRI scanner 30 according to an embodiment;

FIG. 2 shows a first scenario in which a trained transform network unit 20 in FIG. 1 is used;

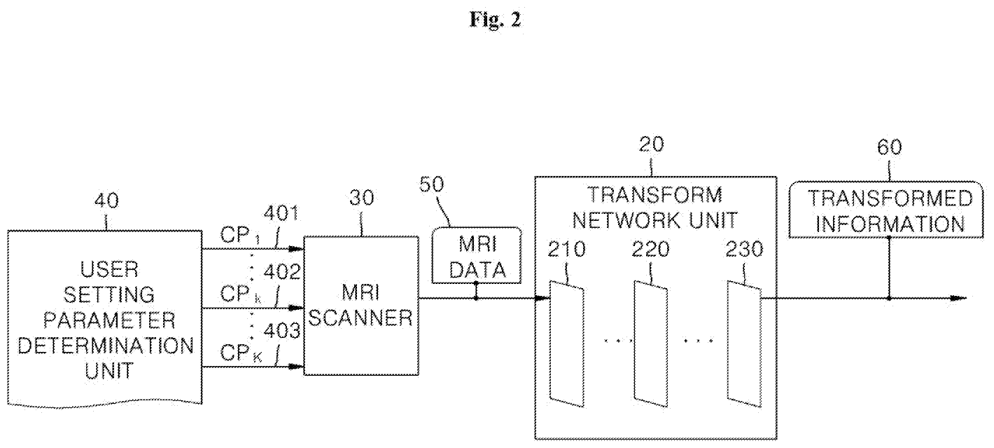

FIG. 3 shows a second scenario in which the trained transform network unit 20 in FIG. 1 is used;

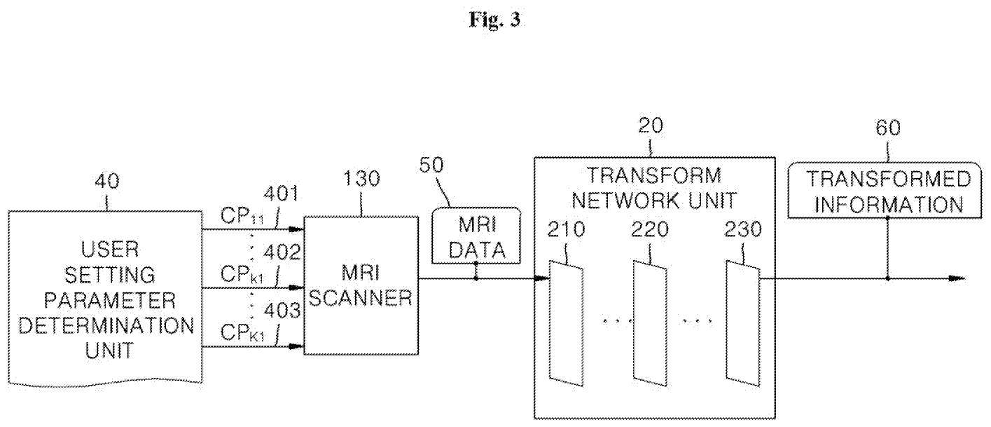

FIG. 4 is a diagram showing a method for transforming MRI data output from the transform network unit according to an embodiment of the present disclosure;

FIG. 5 is for explaining one criterion for classifying device characteristics of two MRI scanners having different device characteristics;

FIG. 6 is a diagram showing a method for training a transform network unit using MRI data output from an MRI scanner according to an embodiment of the present disclosure;

FIG. 7 is a diagram showing a detailed configuration of a parameter conversion unit provided according to an embodiment of the present disclosure shown in FIG. 6;

FIG. 8 shows a manner in which transform parameters, which are output from the parameter conversion unit, are input to a selected layer of the transform network unit according to an embodiment of the present disclosure;

FIG. 9 is a diagram showing the configuration of an MRI data transform device that transforms MRI data using the trained transform network unit in FIG. 6;

FIG. 10 is a flow chart illustrating a method for training the transform network unit provided according to an embodiment of the present disclosure; and

FIG. 11 is a flow chart illustrating a method for generating transformed information using the trained transform network unit provided according to an embodiment of the present disclosure.

### DETAILED DESCRIPTION OF EMBODIMENTS

Hereinafter, exemplary embodiments of the present invention will be described in detail with reference to the accompanying drawings. However, the present invention is not limited to embodiments described herein and can be implemented in various other forms. Terms used herein are for assisting in comprehensive understanding of exemplary embodiments and are not intended to limit the scope of the present invention. In addition, it is to be understood that the singular forms “a,” “an,” and “the” include plural referents unless the context clearly dictates otherwise.

<Training of User Setting Parameters>

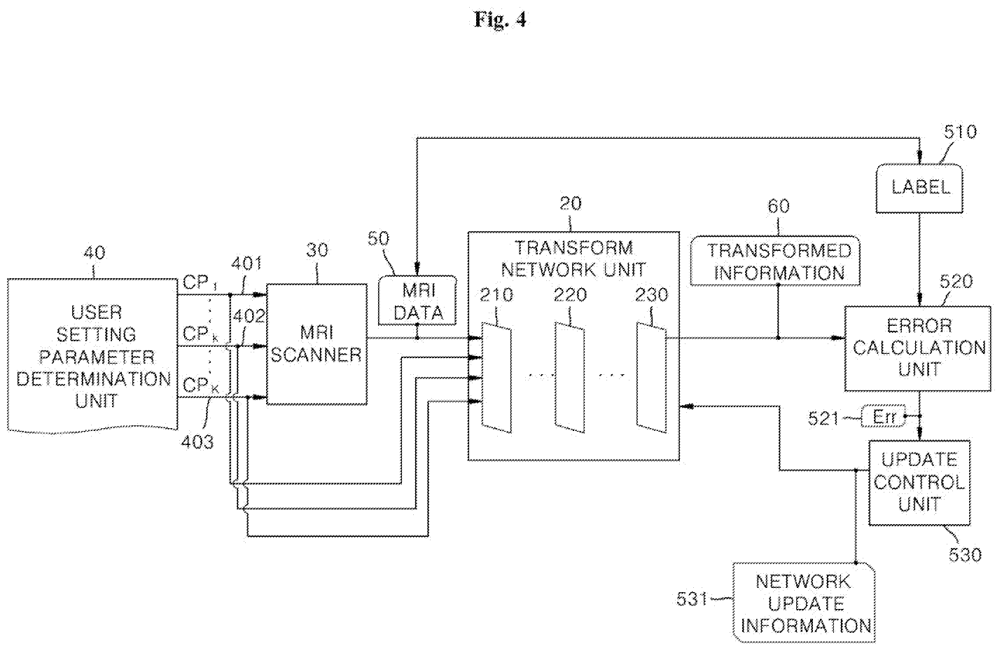

FIG. 4 is a diagram showing a method for transforming MRI data output from the transform network unit according to an embodiment of the present disclosure.

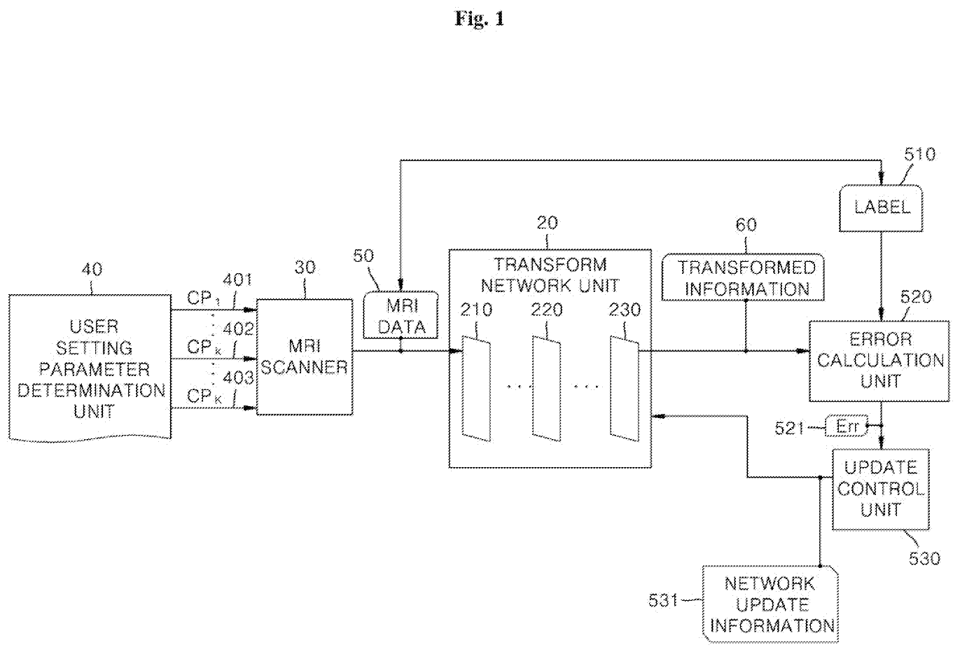

FIG. 4 is different from FIG. 1 in that a plurality of user setting parameters 401, 402, and 403 are input to the input layer of the transform network unit 20 for addressing the issues according to the embodiment explained with reference to FIG. 1.

The values of the plurality of user setting parameters 401, 402, and 403 should be changed in a training process of the transform network unit 20 so that the plurality of user setting parameters 401, 402, and 403 to be input to the transform network unit 20 exert an influence on a trained result of the transform network unit 20. For example, when the entire number of the plurality of user setting parameters is K, and the number of cases in which the combination formed of the plurality of user setting parameters may have is Kc, the number of times of repetitive training for completing training of the transform network unit 20 may increase, for example, Kc times than the case in FIG. 1, where Kc may be a significantly large number. In this case, the computing power and/or the computing time taken to train the transform network unit 20 may be significantly large.

In addition, in a case in which the entire number of scalar values (or vector values) included in the plurality of user setting parameters to be input to the transform network 20 is K1, and the entire number of scalar values (or vector values) included in the MRI data 50 to be input to the transform network 20 is K2, if K2>>K1, the following issues may occur. Namely, since a proportion of the plurality of user setting parameters occupying the values to be input to the transform network 20 becomes, so to speak, K1/(K1+K2) (<<1), the influence exerted by the plurality of user setting parameters on the training of the transform network unit 20 is small.

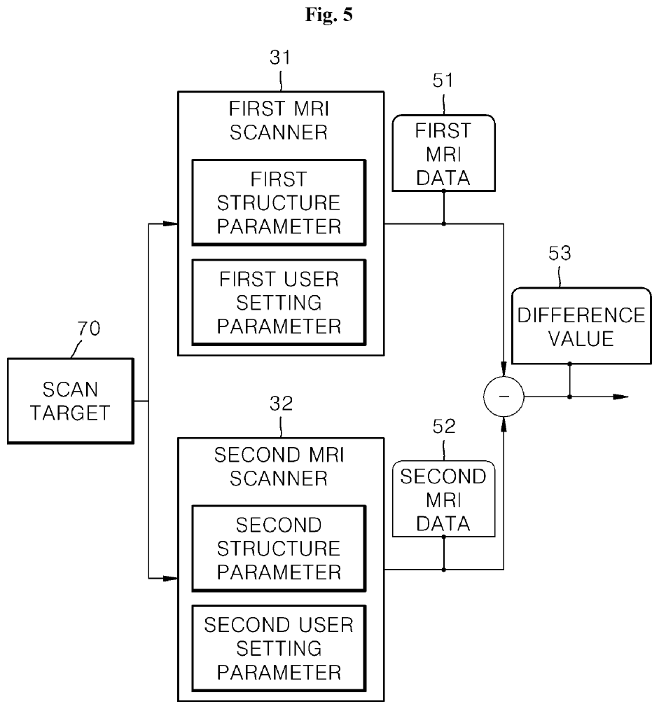

In FIG. 4, the unique device characteristics of the MRI scanner, for which the transform network unit 20 trains, are limited to the above-described plurality of user setting parameters. However, in an embodiment of the present disclosure, the unique device characteristics of the MRI scanner may be further defined besides the plurality of user setting parameters. A description thereabout will be provided with reference to FIG. 5.

<Definition of “Device Characteristics” in the Present Disclosure>

The device characteristics defined in the present disclosure may be understood as divided into two concepts, namely, “structure parameters”, and “user setting parameters”. The device characteristics may also be referred to as operation characteristics.

FIG. 5 is for explaining the structure parameters and the user setting parameters constituting each set of the device characteristics of two MRI scanners having different device characteristics. Hereinafter, descriptions will be provided with reference to FIG. 5.

1. Structure Parameters

The components included in the first MRI scanner 31 may have first structure parameters. The first structure parameters may be parameters obtained by digitizing the various characteristics of the components, for example, the strength of a magnet included in the first MRI scanner 31, the number of coils, maximum power, or the like. The various characteristics of the components may be determined by a design specification of the first MRI scanner 31. In addition, despite of the determined design specification, the various characteristics of the components may be determined by difference deviation in the production process of the first MRI scanner 31. Furthermore, the various characteristics of the components may also be determined according to a degradation degree of each component according to use of the first MRI scanner 31. Furthermore, the first structure parameters may include parameters obtained by digitizing interactions between the various components included in the first MRI scanner 31.

The components included in the second MRI scanner 32 may have second structure parameters. The second structure parameters may be parameters obtained by digitizing various characteristics of the components, for example, the strength of a magnet included in the second MRI scanner 32, the number of coils, maximum power, or the like. The various characteristics of the components may be determined by a design specification of the second MRI scanner 32. In addition, despite of the determined design specification, the various characteristics of the components may be determined by the deviation in the production process of the second MRI scanner 32. Furthermore, the various characteristics of the components may also be determined according to a degradation degree of each component according to use of the second MRI scanner 32. Furthermore the second structure parameters may include parameters obtained by digitizing interactions between the various components included in the second MRI scanner 32.

The first structure parameters, the second structure parameters, and structure parameters defined in another arbitrary MRI scanner may be totally called as the structure parameters.

A structure parameter in the present specification may individually designate one structure parameter, or collectively designate a plurality of structure parameters.

The first and second structure parameters of the first MRI scanner 31 and the second MRI scanner 32, which are different from each other, may be the same or different from each other.

In addition, the number and types of components constituting the first MRI scanner 31 may be the same or different from the number and types of components constituting the second MRI scanner 32.

The device characteristics (=operation characteristics) of the first MRI scanner 31 and the second MRI scanner 32 may be changed by the structure parameters thereof.

The values of the structure parameters may be divided into the easily acquirable and the hardly acquirable. For example, it is easy to obtain the values of the structure parameters changed by the design specification of the MRI scanner. However, even when the design specification is given, it may be hard to obtain structure parameters according to a production process error of the MRI scanner and structure parameters caused by degradation according to the time.

2. User Setting Parameters

Meanwhile, the device characteristics (=operation characteristics) of the first MRI scanner 31 and the second MRI scanner 32 may be changed by the user setting parameters set each of the first MRI scanner 31 and the second MRI scanner 32.

The number and types of the user setting parameters provided by the first MRI scanner 31 may be the same or different from the number and types of the user setting parameters provided by the second MRI scanner 32.

Even when it is assumed that the number and types of the user setting parameters provided by the first MRI scanner 31 are the same as the number and types of the user setting parameters provided by the second MRI scanner 32, if the values of the user setting parameters set to the first MRI scanner 31 are different from those set to the second MRI scanner 32, the operation characteristics of the first scanner 31 and the second scanner 32 may be different from each other.

If the scan target 70 in a first state is scanned with the first MRI scanner 31, the values represented by first MRI data 51 output from the first MRI scanner 31 may be determined by at least the first structure parameters of the first MRI scanner 31 and the first user setting parameters set to the first MRI scanner 31.

Similarly, if the scan target 70 in the first state is scanned with the second MRI scanner 32, the values represented by second MRI data 52 output from the second MRI scanner 32 may be determined by at least the second structure parameters of the second MRI scanner 32 and the second user setting parameters set to the second MRI scanner 32.

In an ideal scenario, the MRI data obtained by scanning the same scan target 70 with two different scanners should be the same.

If first device characteristics formed from the first structure parameters and the first user setting parameters are the same as second device characteristics formed from the second structure parameters and the second user setting parameters, the first MRI data 51 may have the same values as the second MRI data 52.

On the contrary, when the first device characteristics are different from the second device characteristics, the first MRI data 51 may have different values from the second MRI data 52.

In the specification, when there is a difference between MRI data obtained by scanning the same scan target 70 with different MRI scanners, such a difference may be considered as generated by the difference in ‘device characteristics’ between the MRI scanners. The different MRI scanners may have different model numbers or may have the same specification and the same model number. Even when the two MRI scanners have the same model number, different results may be output for the same scan target according to detailed operation conditions.

The foregoing user setting parameters and structure parameters constituting the device characteristics of the MRI scanner may have the following features.

First, there is a feature that the user setting parameters are directly set by a user, and thus the parameter themselves are observed and it is easy to digitize the values thereof.

Second, it may be easy to acquire some of the structure parameters. For example, the strength of a fixed magnetic field of a given MRI scanner may be easily obtainable information.

Third, another portion of the structure parameters includes a hardly observable process error, or hardly observable information such as component degradation according to the time. Accordingly, there are features that it is difficult to observe the structure parameters and even when being observed, it is difficult to quantify the same.

<Extract Data Characteristic Values of MRI Data for Preparing Training with the Device Characteristics of the MRI Scanner>

In this way, despite it is difficult to obtain information about some of the structure parameters, the structure parameters are reflected to the MRI data 50 that is output by the MRI scanner 30. In other words, it may be understood that the influence exerted by the structure parameters is inherent in the MRI data 50 that is output by the MRI scanner 30.

Here, the device characteristics are required to be provided to the transform network unit 20 according to an embodiment of the present disclosure in a training process so that the transform network unit 20 trains the unique device characteristics of the MRI scanner 30. In other words, the user setting parameters 401, 402, and 403 and information about the structure parameters are required to be provided to the transform network unit 20 in the training process.

Here, the values of the user setting parameters 401, 402, and 403 may be easily defined, and thus may be provided to the transform network unit 20 without causing any difficulty.

In addition, some, which may be easily defined and of which numerical values may be easily acquired, of the structure parameters are provided to the transform network unit 20 without causing any difficulty. It will be described later, and such a kind of structure parameters may be acquired by the structure parameter acquisition unit 90 and then provided to the transform network unit 20.

In comparison thereto, it is hard to acquire some structure parameters by defining them with an observable value. Thus, instead of directly acquiring the some structure parameters from the MRI scanner 30 and providing them to the transform network unit 20, a method may also be considered which provides the MRI data, in which the influence exerted by the some structure parameters is inherent, to the transform network unit.

However, a first most important operation target of the transform network unit 20 is to transform the MRI data 50. Accordingly, there is an issue that a lot of pieces of MRI training data and computing resources are consumed so that the transform network unit 20 achieves the first operation target and a second operation target together, the second operation target being for the transform network unit 20 to train and reflect the structure parameters inherent in the MRI data 50.

Accordingly, in the present disclosure, the structure parameters inherent in the MRI data 50 may be extracted in a separate predetermined method.

Data characteristic values 801, 802, and 803 extracted in this way may not be considered as the structure parameters themselves. In the same manner, the MRI data 50 may not be considered as the structure parameters themselves, either.

However, it may be understood that the data characteristic values 801, 802, and 803 expose the characteristics of the some structure parameters more than the MRI data 50 does.

The data characteristic values 801, 802, and 803 may include information determined with an easily acquired value among values pertaining to the hardware and/or software specification of the MRI scanner 30. In addition, the data characteristic values 801, 802, and 803 may include information determined with a value that is not easily acquired among values pertaining to the hardware and/or software specification of the MRI scanner 30.

When there is the difference between a value represented by the first MRI data 51 output from the first MRI scanner 31 and a value represented by the second MRI data 52 output from the second MRI scanner 32, the difference may be quantified according to a prescribed manner.

For example, when the MRI data 50 is image data, various characteristics of the image, which include an SNR, a contrast, and the like of the image and may be extracted through an image processing technology, may be defined. Accordingly, the image characteristics of the image data may be quantified and provided as training materials of the transform network unit 20. In the present specification, such image characteristics are considered as effective train parameters including the information on the structure parameters therein. The values obtained by quantifying the image characteristics may be considered as data characteristic values of the MRI data in the present specification.

The MRI data 50 output from the MRI scanner 30 may have different formats according to cases. For example, when the MRI data is image data, the data characteristic values of the MRI data may be extracted through a well-known image processing technology. When the MRI data is k-space data, the data characteristic values of the MRI data may be extracted through a well-known processing technology in a k-space analysis technology.

In other words, in comparison to a case in which only MRI data 50 itself is input to the transform network unit 20, a training burden of the transform network unit 20 may be reduced by extracting meaningful data characteristic values from the MRI data 50 to provide the extracted values to the transform network unit 20 using domain knowledge previously well-defined in a corresponding technical field in which the data format of the MRI data 50 is used.

<Training Method of Transform Network Unit According to Preferable Embodiment>

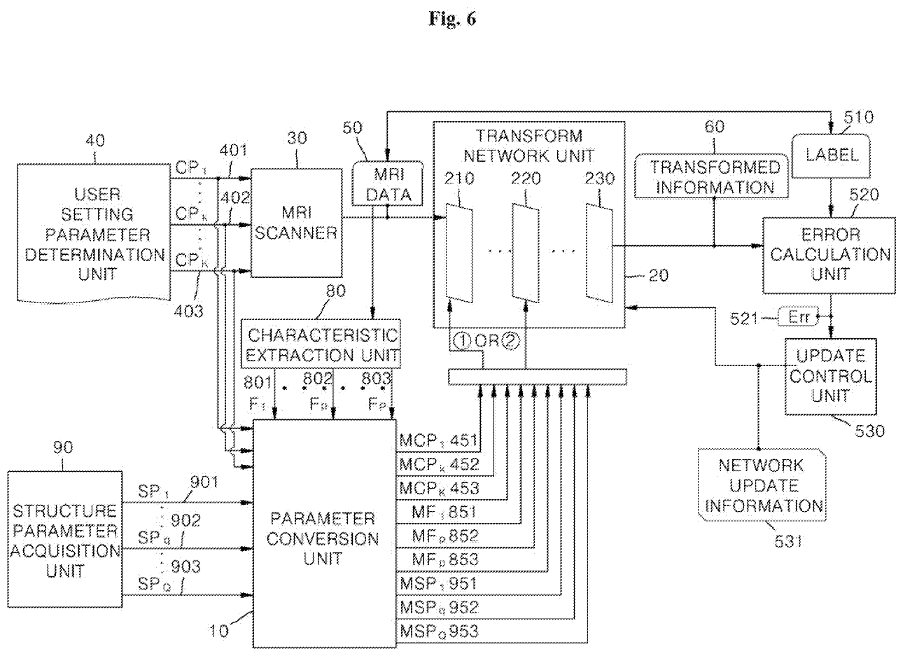

FIG. 6 is a diagram showing a method for training the transform network unit using the MRI data output from the MRI scanner according to an embodiment of the present disclosure.

The training method of the transform network unit according to an embodiment of the present disclosure may perform the following works before one iteration of training for the transform network unit 20.

Before scanning a scan target (not shown) with the MRI scanner 30, various types of the user setting parameters 401, 402, and 403 of the MRI scanner 30 may be determined using the user setting parameter determination unit 40.

Now, the MRI scanner 30 may scan the scan target to output the MRI data 50.

The characteristic extraction unit 80 may extract the data characteristic values from the MRI data 50 using a well-known processing technology in the corresponding technical field using the data format of the MRI data 50.

For example, when the data format of the MRI data 50 is a bitmap image, the corresponding technical field is an image processing technology, and an example of the data characteristic values may be various pieces of information including an SNR, a contrast and the like of the bitmap image. The extracted data characteristic values in FIG. 6 are presented as a plurality of values respectively having reference numerals 801, 802 and 803. Alternatively, the extracted data characteristic values in the present specification may be expressed with reference codes Fₚ (p=1, 2, 3, . . . , P).

The structure parameter acquisition unit 90 may be set to acquire some structure parameters representing a hardware or software specification constituting the MRI scanner 30. The values of the some structure parameters may be directly input by the user to the parameter acquisition unit 90, or may be automatically detected by a separate hardware/software monitoring unit of the MRI scanner to be input to the structure parameter acquisition unit 90.

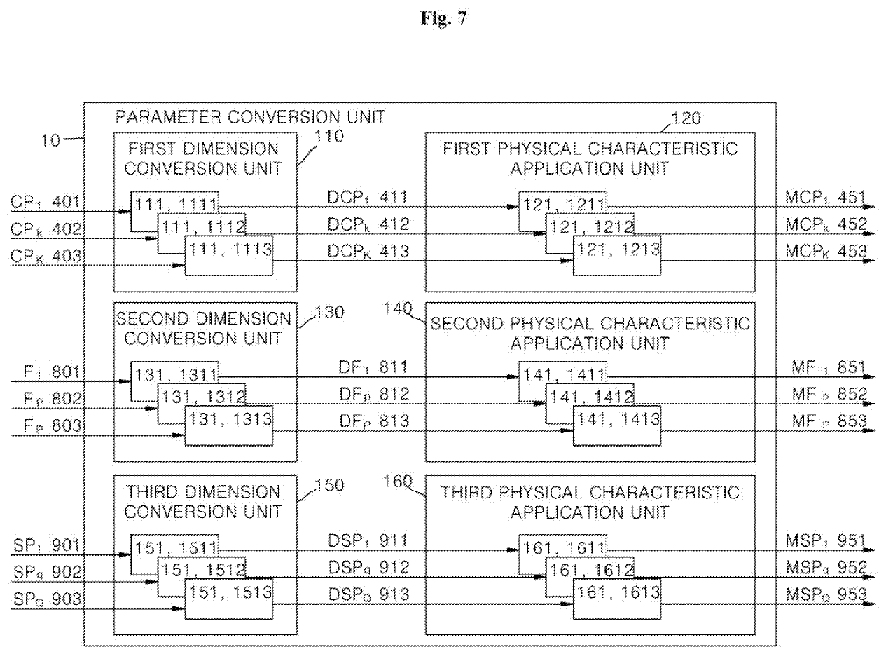

The parameter conversion unit 10 may output conversion parameters 451 to 453, 851 to 853, 951 to 953; MCPₖ, MFₚ, and MSP_{q} obtained by converting the data characteristic values Fₚ extracted from the MRI data 50, the user setting parameters CPₖ, and the structure parameters SP_{q} provided by the structure parameter unit 90 to a predetermined format. An embodiment of a detailed configuration of the parameter conversion unit 10 will be explained with reference to FIG. 7.

In an embodiment, the parameter conversion unit 10 may receive, as an input, only selected values among the data characteristic values Fₚ, the user setting parameters CPₖ, and the structure parameters SP_{q}. For example, the parameter conversion unit 10 only receives, as an input, the data characteristic values Fₚ and the user setting parameters CPₖ, and does not receive the structure parameters SP_{q} as an input. In this case, the conversion parameters 951 to 953; MSP_{q} may not be input to the transform network unit 20.

The conversion parameters 451 to 453, 851 to 853, 951 to 953; MCPₖ, MFₚ, and MSP_{q} may be input to a layer that is included in the transform network unit 20 and is selected on the basis of a prescribed criterion.

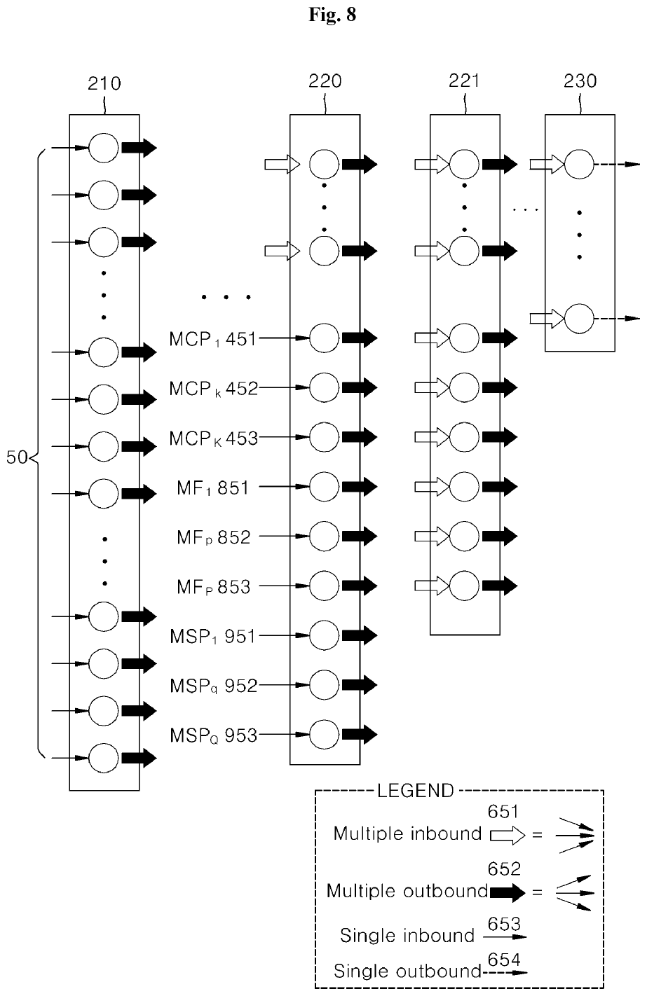

The selected layer may be the input layer 210, but, in a preferred embodiment, may be the hidden layer 220 present in the downstream of the input layer 210. A more detailed method in which the conversion parameters 51 to 453, 851 to 853, 951 to 953; MCPₖ, MFₚ, MSP_{q} may be input to the selected layer in the transform network unit 20 will be described with reference to FIG. 8.

According to an embodiment, the parameter conversion unit 10 may output at least some of the input data without conversion. In an embodiment in which the input data is entirely output without conversion, the configuration of the parameter conversion unit 10 may be omitted in FIG. 6.

In this way, when the MRI data 50 and the conversion parameters 51 to 453, 851 to 853, 951 to 953; MCPₖ, MFₚ, and MSP_{q} are all prepared, the transform network unit 20 performs one iteration of supervised training using the MRI data 50, the conversion parameters 51 to 453, 851 to 853, 951 to 953; MCPₖ, MFₚ, and MSP_{q} and the label 510 corresponding to the MRI data 50.

Here, when the supervised training is repeated for various scan targets and various combination value of the user setting parameters, the training of the transform network unit 20 may be completed.

<Embodiments of Parameter Conversion Unit>

FIG. 7 is a diagram showing a detailed configuration of the parameter conversion unit provided according to an embodiment of the present disclosure shown in FIG. 6.

The parameter conversion unit 10 may include a first dimension conversion unit 110, a first physical characteristic application unit 120, a second dimension conversion unit 130, a second physical characteristic application unit 140, a third dimension conversion unit 150, and a third physical characteristic application unit 160.

1. Conversion of User Setting Parameters

A data format of the arbitrary user setting parameters CPₖ may not be suitable for the structure and data format of a layer to which the arbitrary user setting parameters CPₖ should be input. For example, the arbitrary user setting parameters CPₖ have scalar values, but a portion of the layer to which the arbitrary user setting parameter CPₖ should be input may be constituted of a plurality of nodes. In addition, in an embodiment, the plurality of nodes may be given as a matrix type.

The first dimension conversion unit 110 may convert the arbitrary user setting parameters CPₖ to be suitable for a data format of the portion of the layer to which the arbitrary user setting parameters CPₖ should be input. For example, according to the conversion, the arbitrary user setting parameters CPₖ having scalar values may be converted to a dimension conversion value DCPₖ having a matrix type. Each of the numbers of the rows and columns of the dimension conversion value DCPₖ having a matrix type may comply with a predetermined rule. In this way, the dimension of the arbitrary user setting parameters CPₖ may be extended by the first dimension conversion unit 110.

In an embodiment, the first dimension unit 110 may include a plurality of sub-dimension conversion units 111; 1111, 1112, and 1113, Different user setting parameters CPₖ may be input to different sub-dimension conversion units 111. Each of the sub-dimension conversion units 111 may convert the input user setting parameters according to the predetermined rule to output the dimension conversion value DCPₖ. The numbers of the rows and columns of each output dimension conversion value DCPₖ may be converted to be suitable for a data format of each part of the layer to which the dimension conversion value DCPₖ should be input, namely, the layer to which the user setting parameters CPₖ corresponding to the dimension conversion value DCPₖ.

The first physical characteristic application unit 120 may generate a conversion parameter MCPₖ obtained by converting the dimension conversion value DCPₖ.

In an embodiment, different dimension conversion values DCPₖ may be respectively converted by different sub-characteristic application units 121. In other words, the different user setting parameters CPₖ corresponding to the different dimension conversion values DCPₖ may be converted by the different sub-characteristic application units 121.

In an embodiment, each of the user setting parameters CPₖ may be a parameter representing various physical characteristics explaining the operation principle of the MRI scanner. In addition, the physical characteristics represented with the different user setting parameters CPₖ may be different from each other. Here, each of the sub-characteristic application unit 121 may have the input and output characteristics based on the physical characteristics of the user setting parameter CPₖ corresponding to itself.

In an embodiment, at least one user setting parameter CPₖ may not be to describe the physical characteristics.

In an embodiment, at least one sub-characteristic application unit 121 may be actually omitted.

Now, a process in which one user setting parameter is converted to one conversion parameter will be exemplified. For example, the first user setting parameter CP₁ 401 may be converted to the first dimension conversion value DCP₁ 411 by the first sub-dimension conversion unit 1111, and the first dimension conversion value DCP₁ 411 may be converted to the first conversion parameter MCP₁ by the first sub-characteristic application unit 1211. Similarly, a k-th user setting parameter CPₖ 402 may be converted to a k-th dimension conversion value DCPₖ 412 by a k-th sub-dimension conversion unit 1112, and a k-th dimension conversion value DCPₖ 412 may be converted to a k-th conversion parameter MCPₖ by a k-th sub-characteristic application unit 1212.

Here, the physical characteristics shown by the first user setting parameter CP₁ 401 and the k-th user setting parameter CPₖ 402 may be different from each other. Accordingly, the input and output characteristics of the first sub-characteristic application unit 1211 and the k-th sub-characteristic application unit 1212 may be different from each other.

2. Conversion of Data Characteristic Value.

Similarly, a data format of an arbitrary data characteristic value Fₚ may not be suitable for the structure and data format of a layer to which the data characteristic value Fₚ should be input.

The second dimension conversion unit 130 may convert the arbitrary data characteristic value Fₚ to be suitable for a data format of the portion of the layer to which the arbitrary data characteristic value Fₚ should be input. The dimension of the arbitrary data characteristic value Fₚ may be extended by the second dimension conversion unit 130.

In an embodiment, the second dimension unit 130 may include a plurality of sub-dimension conversion units 131. The functions of the plurality of sub-dimension conversion units 131 may be the same as those of the plurality of sub-dimension conversion units 111. The second dimension conversion unit 130 may generate a dimension conversion value DFₚ from the data characteristic value Fr.

The second physical characteristic application unit 140 may generate a conversion parameter MFₚ obtained by converting the dimension conversion value DFₚ. In an embodiment, different dimension conversion values DFₚ may be respectively converted by different sub-characteristic application units 141. In other words, the different data characteristic values Fₚ corresponding to the different dimension conversion values DFₚ may be converted by the different sub-characteristic application units 141.

In an embodiment, each of the data characteristic values Fₚ may be a parameter representing the physical characteristics of the MRI data 50. In addition, the physical characteristics represented with the different data characteristic values Fₚ may be different from each other. Here, each of the sub-characteristic application unit 141 may have the input and output characteristics based on the physical characteristics of the data characteristic value Fₚ corresponding to itself.

Here, when the physical characteristics represented by the first data characteristic value Fi and a p-th data characteristic value Fₚ are different from each other, the input and output characteristic values of the first sub-characteristic application unit 1411 and the k-th sub-characteristic application unit 1412 may be different from each other.

In an embodiment, at least one data characteristic value Fₚ may not be to describe the physical characteristics.

In an embodiment, at least one sub-characteristic application unit 141 may be actually omitted.

3. Conversion of Structure Parameters

A data format of the arbitrary structure parameter SP_{q} may not be suitable for the structure and data format of a layer to which the arbitrary structure parameters SP_{q} should be input. For example, the arbitrary structure parameters SP_{q} have scalar values, but a portion of the layer to which the arbitrary structure parameters SP_{q} should be input may be constituted of a plurality of nodes. In addition, in an embodiment, the plurality of nodes may be given as a matrix type.

The third dimension conversion unit 150 may convert the arbitrary structure parameters SP_{q} to be suitable for a data format of the portion of the layer to which the arbitrary structure parameters SP_{q} should be input. For example, according to the conversion, the arbitrary structure parameters SP_{q} having scalar values may be converted to a dimension conversion value DSP_{q} having a matrix type. Each of the numbers of the rows and columns of the dimension conversion value DSP_{q} having a matrix type may comply with a predetermined rule. In this way, the dimension of the structure parameters SP_{q} may be extended by the third dimension conversion unit 150.

In an embodiment, the third dimension unit 150 may include a plurality of sub-dimension conversion units 151; 1511, 1512, and 1513, Different structure parameters SP_{q} may be input to different sub-dimension conversion units 151. Each of the sub-dimension conversion units 151 may convert the input structure parameters according to the predetermined rule to output the dimension conversion value DSP_{q}. The numbers of the rows and columns of each output dimension conversion value DSP_{q} may be converted to be suitable for a data format of each portion of the layer to which the dimension conversion value DSP_{q} should be input, namely, the layer to which the structure parameters SP_{q} corresponding to the dimension conversion value DSP_{q}.

The third physical characteristic application unit 160 may generate a conversion parameter MSP_{q} obtained by converting the dimension conversion value DSP_{q}.

In an embodiment, different dimension conversion values DSP_{q} may be respectively converted by different sub-characteristic application units 161. In other words, the different structure parameters SP_{q} corresponding to the different dimension conversion values DSP_{q} may be converted by the different sub-characteristic application units 161.

In an embodiment, each of the structure parameters SP_{q} may be a parameter representing various physical characteristics explaining the operation principle of the MRI scanner. In addition, the physical characteristics represented with the different structure parameters SP_{q} may be different from each other. Here, each of the sub-characteristic application unit 161 may have the input and output characteristics based on the physical characteristics of the structure parameter SP_{q} corresponding to itself.

In an embodiment, at least one structure parameter SP_{q} may not be to describe the physical characteristics.

In an embodiment, at least one of the sub-characteristic application unit 161 may be actually omitted.

Now, a process in which one structure parameter is converted to one conversion parameter will be exemplified. For example, the first structure parameter SP₁ 901 may be converted to the first dimension conversion value DSP₁ 911 by the first sub-dimension conversion unit 1511, and the first dimension conversion value DSP₁ 911 may be converted to the first conversion parameter MSP₁ by the first sub-characteristic application unit 1611. Similarly, a k-th structure parameter SP_{q} 902 may be converted to a k-th dimension conversion value DSP_{q} 912 by a k-th sub-dimension conversion unit 1512, and a k-th dimension conversion value DSP_{q} 912 may be converted to a k-th conversion parameter MSP_{q} by a k-th sub-characteristic application unit 1612.

Here, the physical characteristics shown by the first structure parameter SP₁ 901 and the k-th structure parameter SP_{q} 902 may be different from each other. Accordingly, the input and output characteristics of the first sub-characteristic application unit 1611 and the k-th sub-characteristic application unit 1612 may be different from each other.

FIG. 7 shows one configuration of the parameter conversion unit 10, and the present disclosure is not limited to this detailed configuration.

<Method for Inputting Conversion Parameters to Transform Network Unit>

FIG. 8 shows a manner in which transform parameters output from the parameter conversion unit are input to a selected layer of the transform network unit according to an embodiment of the present disclosure.

A reference numeral 210 in FIG. 8 denotes an input layer, reference numerals 220 and 221 denote hidden layers, and a reference numeral 230 denotes an output layer.

The MRI data 50 is input to the input layer 210, but the conversion parameters 451 to 453, 851 to 853, 951 to 953; MCPₖ, MFₚ, and MSP_{q} output from the parameter conversion unit 10 are not input to the input layer 210.

In FIG. 8, circles indicate nodes of a neural network, a first arrow 651 indicates that a plurality of inbound links come towards a node to which the head of the arrow points, a second arrow 652 indicates that a plurality of outbound links go out from a node at which the tail of the arrow is positioned, a third arrow 653 indicates that only one inbound link comes toward a node to which the head of the arrow points, and a fourth arrow 654 indicates that only one output bound link goes out from a node at which the tail of the arrow is positioned.

In the example shown in FIG. 8, the conversion parameters 451 to 453, 851 to 853, 951 to 953; MCPₖ, MFₚ, and MSP_{q} are input to a plurality of nodes selected from the hidden layer 220. In other words, the values of the plurality of selected nodes may be determined by the 451 to 453, 851 to 853, 951 to 953; MCPₖ, MFₚ, and MSP_{q}. In addition, as shown, only one inbound link is connected to each of the plurality of selected nodes. Accordingly, the values of the plurality of selected nodes of the hidden layer 220 may be determined only by the 451 to 453, 851 to 853, 951 to 953; MCPₖ, MFₚ, and MSP_{q}.

Here, the number of nodes constituting the input layer 20 is smaller than the number of nodes constituting the hidden layer 220.

As shown in FIG. 8, when the conversion parameters 451 to 453, 851 to 853, 951 to 953; MCPₖ, MFₚ, and MSP_{q} are not input to the input layer 210 but input to the hidden layer 220, there are advantageous effects as the followings.

For example, when the MRI data 50 to be input to the input layer 210 is gray-scale image data composed of N1 pixels, at least N1 nodes may be present in the input layer 210.

Meanwhile, the hidden layer 220 of the transform network unit 20 may be constituted with N2 nodes significantly smaller than N1.

If the conversion parameters 451 to 453, 851 to 853, 951 to 953; MCPₖ, MFₚ, and MSP_{q} are input to the input layer 210, a first proportion of the conversion parameters occupying the entire size of the input layer 210 will be {size of conversion parameters}/{N1}.

In contrast, when the conversion parameters are input to the hidden layer 220, a second proportion of the conversion parameters occupying the entire size of the hidden layer 220 will be {size of conversion parameters}/{N2}.

Here, the second ratio is larger than the first ratio. When the conversion parameters, which are considered as important training parameters in the present disclosure, are input to a selected layer, there is an advantageous effect in which training may be performed in a more rapid speed, as a proportion of the conversion parameters occupying the selected layer becomes higher.

<Conversion MRI Data Using Trained Transform Network Unit>

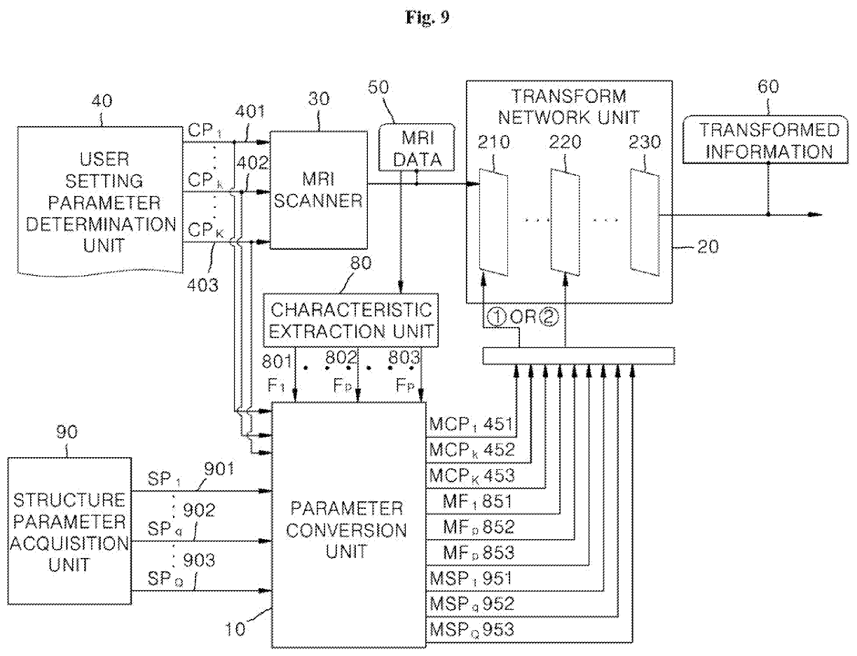

FIG. 9 is a diagram showing the configuration of an MRI data transform device for transforming MRI data using the trained transform network unit in FIG. 6.

The MRI data transform device 1 may include the transform network unit 20 and the characteristic extraction unit 80.

In addition, the MRI data transform device 1 may further include a user setting parameter acquisition unit for acquiring the user setting parameters set to the MRI scanner 30.

In addition, the MRI data transform device 1 may further include a structure parameter acquisition unit 90 for acquiring the structure parameters representing the hardware or software specification constituting the MRI scanner 30.

In addition, the MRI data transform device 1 may further include a parameter conversion unit 10.

In addition, the MRI data transform device 1 may further include the MRI scanner 30 and a user setting parameter determination unit 40.

First, in FIG. 9, the user setting parameter determination unit 40 may set the user setting parameters CPₖ of the MRI scanner 30.

Then, the MRI scanner 30 may output the MRI data 50 generated by scanning a scan target.

Then, the characteristic extraction unit 80 may calculate the data characteristic values Fₚ from the MRI data 50.

Then, the structure parameter acquisition unit 90 may acquire the structure parameters, which represent the hardware or software specification constituting the MRI scanner 30, to output the acquired structure parameters SP_{q}.

Then, the parameter conversion unit 10 may convert the set user setting parameters CPₖ, the calculated data characteristic values Fₚ, and the structure parameters SP_{q} to the conversion parameters 451 to 453, 851 to 853, 951 to 953; MCPₖ, MFₚ, and MSP_{q}.

Then, when the MRI data 50 and the conversion parameters 451 to 453, 851 to 853, 951 to 953; MCPₖ, MFₚ, and MSP_{q} are input to designated input nodes of the transform network unit 20 and the transform network 20 is operated, the transform network unit 20 may output transformed information 60 obtained by transforming the MRI data 50.

<Training Method of Transform Network Unit>

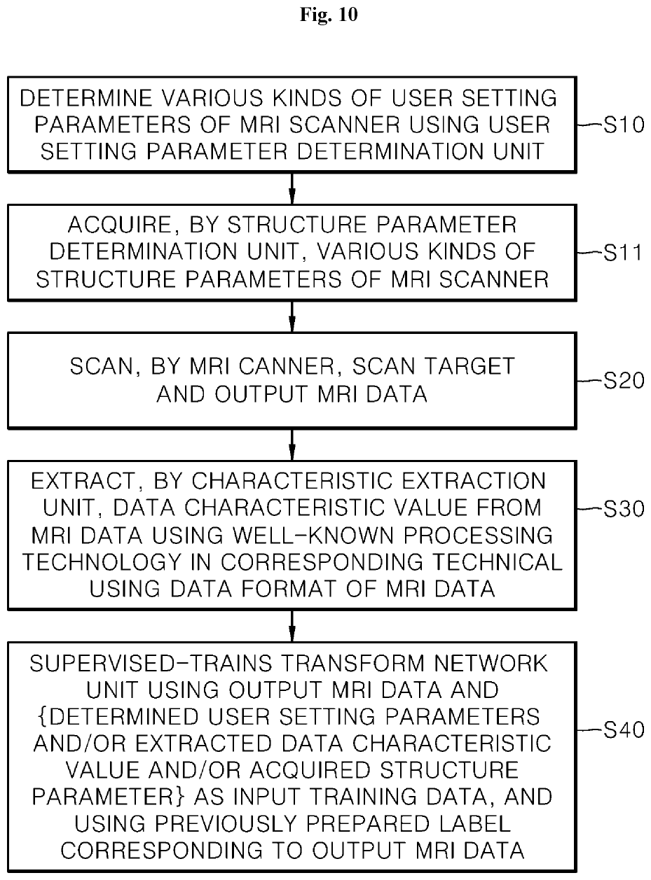

FIG. 10 is a flow chart illustrating a method for training the transform network unit provided according to an embodiment of the present disclosure.

In operation S10, the user setting parameter determination unit 40 may determine various kinds of the user setting parameters CPₖ of the MRI scanner 30.

In operation S11, the structure parameter determination unit 90 may acquire various kinds of the structure parameters SP_{q} of the MRI scanner 30.

In operation S20, the MRI scanner 30 may scan a scan target and output the MRI data 50.

In operation S30, the characteristic extraction unit 80 may extract the data characteristic value Fₚ from the MRI data 50 using a well-known processing technology in the corresponding technical field using the data format of the MRI data 50.

In operation 40, the transform network unit may be supervised-trained using the output MRI data 50 and {the determined user setting parameters CPₖ and/or the extracted data characteristic value Fₚ and/or the acquired structure parameters SP_{q}} as input training data, and using a previously prepared label corresponding to the output MRI data.

<Generation Method for Transformed Information>

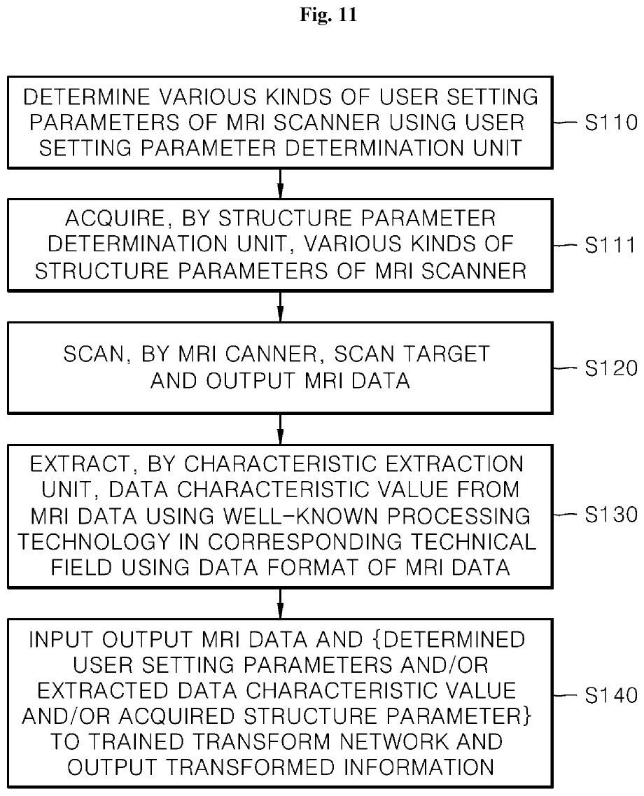

FIG. 11 is a flow chart illustrating a method for generating transformed information using the trained transform network unit provided according to an embodiment of the present disclosure.

In operation S110, the user setting parameter determination unit 40 may determine various kinds of the user setting parameters CPₖ of the MRI scanner 30.

In operation S111, the structure parameter determination unit 90 may acquire various kinds of the structure parameters SP_{q} of the MRI scanner 30.

In operation S120, the MRI scanner 30 may scan the scan target and output the MRI data 50.

In operation S130, the characteristic extraction unit 80 may extract the data characteristic value Fₚ from the MRI data 50 using a well-known processing technology in the corresponding technical field using the data format of the MRI data 50.

In operation 140, the transformed information may be output by inputting, to the trained transform network unit, the output MRI data 50 and {the determined user setting parameters CPₖ and/or the extracted data characteristic value Fₚ and/or the acquired structure parameters SP_{q}}.

The MRI scanner 30 presented in the present disclosure may be a device according to a well-known technology including, for example, a main magnet for polarizing a sample, a shim coil for correcting the inhomogeneity of a main magnetic field, an RF system for exciting the sample and sensing a nuclear magnetic resonance (NMR) signal, and a gradient system used for localizing the MR signal. This entire system may be controlled by one or more computers.

In an embodiment of the present disclosure, the transform network unit 20 and/or the feature extraction unit 80, and/or the parameter conversion unit 10 may be implemented with software installed in a general purpose computer. In this case, the MRI data 50 may be provided to the general purpose computer as input information, and the transformed information 60 may be output by the general purpose computer.

In another embodiment of the present disclosure, the transform network unit 20 and/or the feature extraction unit 80, and/or the parameter conversion unit 10 may be provided with a dedicated computing device for providing functions thereof. The dedicated computing device may be a device including an field-programmable gate array (FPGA) and/or a digital signal processor (DSP).

Here, as a device for providing information about the structure parameters through a data input interface of the general purpose computer or the dedicated computing device, the structure parameter acquisition unit 90 may be a user input interface that is directly operated by a human, or an automated computing device that directly searches the structure parameters of the MRI scanner 30 from the MRI scanner 30 to automatically provide the searched result to the general purpose computer or the dedicated computing device.

The structure parameter acquisition unit 90 may be provided in an integrated type with a device including the transform network unit 20, or provided as a separate device.

The user setting parameter determination unit 40 may be provided in an integrated type with the MRI scanner 30, or provided as a separate deice.

According to the present disclosure, a technology may be provided which maintains transform performance of a trained transform network unit at a constant level in various situations in which the unique device characteristics of an MRI scanner to which the trained transform network unit should be applied are not guaranteed to have predetermined reference conditions.

Although the present invention been described with reference to the specific embodiments, it is not limited thereto. Therefore, it will be readily understood by those skilled in the art that various modifications and changes can be made thereto without departing from the spirit and scope of the present invention defined by the appended claims. The contents of each of the claims herein can be combined to any other that is not dependent therefrom within an understandable scope through the specification.

<Bibliographic Information 1>

1) Unique project number: 2018R1A2B3008445

2) Department name: Ministry of Science and ICT

3) Research and Management Institution: National Research Foundation of Korea

4) Research program title: Basic Research Program in Science and Engineering/Middle-Grade Researcher Supporting Program

5) Research project title: Research on method for imaging quantitative cerebral fine structure information

6) Host Institution: Seoul national university Industry-Academic Cooperation Foundation

7) Research period: May 1, 2019-Feb. 29, 2020

<Bibliographic Information 2>

1) Department name: Private project (Samsung Electronics)

2) Research and Management Institution: Samsung Electronics

3) Research program title: Samsung future technology incubation project

4) Research program title: Development of core component technology for next-generation ultra high magnetic field and high-temperature superconducting whole-body MRI magnet

5) Host Institution: Seoul national university Industry-Academic Cooperation Foundation

6) Research period: Jun. 1, 2018-May 31, 2021

1. An MRI data transform device comprising:
a transform network unit configured to output prescribed transformed information on a basis of MRI data output from an MRI scanner,
wherein, in order to output the transformed information, the MRI data and information about device characteristics of the MRI scanner are provided to the transform network unit.

2. The MRI data transform device of claim 1, wherein the information about the device characteristics comprises a data characteristic value calculated from the MRI data in a predetermined manner.

3. The MRI data transform device of claim 1, wherein the information about the device characteristics comprises a user setting parameter of the MRI scanner.

4. The MRI data transform device of claim 1, wherein the information about the device characteristics comprises a structure parameter representing a specification of a hardware or a software constituting the MRI scanner.

5. The MRI data transform device of claim 1, wherein
the transform network unit comprises a multilayer neural network, and
the information about the device characteristics is input to a hidden layer of the neural network.

6. The MRI data transform device of claim 5, wherein
the information about the device characteristics is input a set of nodes forming the hidden layer, and
the information input to the set of nodes comprises only information about the device characteristics.

7. The MRI data transform device of claim 6, wherein a number of nodes constituting a third layer connected to an outbound link of an arbitrary node among the one set of nodes is smaller than a number of nodes constituting an input layer of the neural network.

8. The MRI data transform device of claim 2, wherein the MRI data is image data, and the data characteristic value comprises one or more among an SNR, a contrast, and an aliasing pattern of the image data.

9. The MRI data transform device of claim 1, further comprising:
a parameter conversion unit,
wherein the transform network unit comprises a multilayer neural network, and the parameter conversion unit is configured to acquire a user setting parameter of the MRI scanner, to convert the acquired user setting parameter, and to provide the converted user setting parameter to a hidden layer of the neural network.

10. The MRI data transform device of claim 1, wherein,
the information about the device characteristics comprises a user setting parameter of the MRI scanner, and
the MRI data transform device further comprises:
a dimension conversion unit configured to convert a dimension of the user setting parameter to output a first dimension conversion value; and
a physical characteristic application unit configured to convert the first dimension conversion value on a basis of a first conversion function determined according to a physical meaning of the user setting parameter to output a first conversion parameter.

11. The MRI data transform device of claim 3, wherein the user setting parameter comprises a scan parameter of the MRI scanner.

12. An MRI data transform method comprising:
determining, by a user setting parameter determination unit of an MRI data transform device, user setting parameters of an MRI scanner;
scanning, by the MRI scanner of the MRI data transform device, a given scan target to output MRI data;
extracting, a characteristic extraction unit of the MRI data transform device, a data characteristic value of the MRI data; and
inputting, by the MRI data transform device, not only the outputted MRI data but also one or more among the determined user setting parameters and the extracted data characteristic value to a trained transform network unit, and outputting prescribed transformed information from the trained transform network unit.

13. The MRI data transform method of claim 12, wherein
the MRI data transform device has been trained by a training method,
wherein the training method comprises:
determining, by the user setting parameter determination unit of the MRI data transform device, the user setting parameters of the MRI scanner;
scanning, by the MRI scanner of the MRI data transform device, the given scan target to output the MRI data;
extracting, by the characteristic extraction unit of the MRI data transform device, the data characteristic value of the MRI data; and
supervised-training, by the transform network unit of the MRI data transform device, using the output MRI data and a previously prepared label corresponding to the outputted MRI data,
wherein input training data for the supervised-training comprises not only the outputted MRI data, but also one or more among the determined user setting parameters and the extracted data characteristic value.

14. An MRI data transform device comprising:
a transform network unit configured to output prescribed transform information transformed from first MRI data on a basis of the first MRI data, which is output by a first MRI scanner that has scanned a scan target,
wherein, for outputting the transform information, the MRI data transform device provides the MRI data and information about device characteristics of the MRI scanner to the transform network unit,
wherein the device characteristics of the first MRI scanner is formed of parameter values causing a difference between the first MRI data and second MRI data, wherein the second MRI data is outputted by a second MRI scanner which has scanned the scan target, wherein the second MRI scanner is different from the first MRI scanner.

15. The MRI data transform device of claim 14, wherein the parameter values comprise one or more among a user setting parameter for determining an operation state of the first MRI data, a structure parameter representing a specification of a first hardware constituting the first MRI scanner, and a data characteristic value acquired from the first MRI data.

16. The MRI data transform device of claim 2, wherein the information about the device characteristics comprises a user setting parameter of the MRI scanner.

17. The MRI data transform device of claim 2, wherein the information about the device characteristics comprises a structure parameter representing a specification of a hardware or a software constituting the MRI scanner.
